(19) United States
(12) Patent Application Publication
(10) Pub. No.: US 2026/0332084 A1
(43) Pub. Date: Oct. 22, 2026

(54) SAFE TORQUE OFF CIRCUIT

(71) Applicant: Eaton Intelligent Power Limited, Dublin (IE)

(72) Inventors: Hua Qiang Li, Menomonee Falls, WI (US); Xiaoling Li, Guangdong (CN); Yuemeng Chang, Guangdong (CN)

(21) Appl. No.: 19/642,797

(22) Filed: Apr. 9, 2026

(30) Foreign Application Priority Data
Apr. 21, 2025 (CN) 202510503117.X

(51) Int. Cl. H02P 29/024; H02P 3/02; H02P 3/06; H03K 7/08; H03K 19/094

(52) U.S. Cl. CPC H02P 29/0241; H02P 3/02; H02P 3/06; H03K 7/08; H03K 19/09421

(57) ABSTRACT

In one aspect, a system includes: a safe torque off (STO) circuit including a controllable switch, the STO circuit configured to generate a control signal for a device. The control signal has a first state that enables the device when the controllable switch is ON, and the control signal has a second state that does not enable the device when the controllable switch is OFF. The system also includes an electronic control configured to generate a diagnostic signal when the control signal has the first state; and a diagnostic circuit configured to: modify a voltage of the diagnostic signal to produce a modified diagnostic signal and provide the modified diagnostic signal to the STO circuit to produce an output signal. The modified diagnostic signal includes a pulse with a voltage expected to turn OFF the controllable switch. The electronic control is also configured to compare the output signal to a specification, and, if the output signal does not meet the specification, generate a fault signal.

### CROSS-REFERENCE TO RELATED APPLICATION

This application claims priority to Chinese Patent Application No. 202510503117.X, filed Apr. 21, 2025 and titled SAFE TORQUE OFF CIRCUIT, which is incorporated herein by reference in its entirety.

### TECHNICAL FIELD

This disclosure relates to a safe torque off circuit.

### BACKGROUND

Safe torque off (STO) may be used with a motor drive system, such as a direct current (DC) variable speed drive, an alternating current (AC) variable frequency drive, a servo drive, or a stepper drive. STO may be used where force-producing power removal is needed to prevent an unexpected start-up of the motor drive.

### SUMMARY

In one aspect, a system includes: a safe torque off (STO) circuit including a controllable switch, the STO circuit configured to generate a control signal for a device. The control signal has a first state that enables the device when the controllable switch is ON, and the control signal has a second state that does not enable the device when the controllable switch is OFF. The system also includes an electronic control configured to generate a diagnostic signal when the control signal has the first state; and a diagnostic circuit configured to: modify a voltage of the diagnostic signal to produce a modified diagnostic signal and provide the modified diagnostic signal to the STO circuit to produce an output signal. The modified diagnostic signal includes a pulse with a voltage expected to turn OFF the controllable switch. The electronic control is also configured to compare the output signal to a specification, and, if the output signal does not meet the specification, generate a fault signal.

Implementations may include one or more of the following features.

The specification may be an expected voltage range for the output signal when the controllable switch is OFF, and the output signal does not meet the specification if the voltage of the output signal is outside of the expected voltage range. The diagnostic circuit may be configured to: provide the modified diagnostic signal to the STO circuit at a diagnostic node, and the voltage of the pulse is the same or greater than a voltage that a stop signal received at the STO circuit is expected to produce at the diagnostic node.

The controllable switch may include a transistor.

The diagnostic circuit may include a level shifter. The level shifter may include a Zener diode.

The electronic control may be configured to compare a first portion of the output signal to a first specification, and a second portion of the output signal to a second specification. The first specification may be an expected voltage range for the output signal when the controllable switch is ON, and the second specification may be an expected voltage range for the output signal when the controllable switch is OFF.

The electronic control may be further configured to identify the output signal.

The system also may include the device. The device may include a pulse width modulation (PWM) driver signal switch configured to output PWM signals when enabled.

The system also may include a low pass filter between the STO circuit and the device, the low pass filter configured to prevent the modified diagnostic signal from reaching the device.

In some implementations, if the output signal does not meet the specification, the electronic control is further configured to provide the fault signal to the device such that device transitions to a not enabled state.

In another aspect, a control system is configured to: generate a diagnostic signal having a period, and the diagnostic signal being LOW during a first portion of the period and HIGH during a second portion of the period; provide the diagnostic signal to a boosting module to produce an output voltage of a safe torque off (STO) circuit; sample the output voltage at one or more times during a first time window, the first time window corresponding to the first portion of the period; compare the one or more voltages sampled during the first time window to a first voltage specification; sample the output voltage during a second time window, the second time window corresponding to the second portion of the period; compare the voltage sampled during the second time window to a second voltage specification; and if the voltage sampled during the second time window does not meet the second voltage specification, generate a fault signal.

Implementations may include one or more of the following features.

The output voltage may be sampled more than one time during the first time window, and the control system may be configured to generate the fault signal if the voltages sampled in the second time window does not meet the second voltage specification and if all of the voltage sampled in the first time window do not meet the first voltage specification.

The first voltage specification may include a voltage range expected when a controllable switch in the STO circuit is ON, and the second voltage specification may include a voltage range expected when the controllable switch in the STO circuit is OFF.

The control system may be configured to generate the diagnostic signal in response to determining that a control signal generated by the STO circuit is in an enabled state.

The control system may be further configured to: after the period ends, if the voltages sampled during the first time window meet the first voltage specification and the voltage sampled in the second time window meets the second voltage specification, generate a second diagnostic signal having the period; provide the second diagnostic signal to a second boosting module to produce a second output voltage in a second safe torque off (STO) circuit; sample the second output voltage at one or more times during a first time window, the first time window corresponding to the first portion of the period of the second diagnostic signal; compare the one or more voltages sampled during the first time window to the first voltage specification; sample the output voltage during a second time window, the second time window corresponding to the second portion of the period of the second diagnostic signal; compare the voltage sampled during the second time window to the second voltage specification; and if the voltage sampled during the second time window does not meet the second voltage specification, generate a fault signal.

In another aspect, a diagnostic module for an STO circuit includes: an input configured to receive a diagnostic voltage pulse; an inverting element configured to invert the diagnostic voltage pulse into an inverted diagnostic voltage pulse; and a voltage boosting element configured to modify the voltage of the inverted diagnostic voltage pulse into a modified pulse and to inject the modified pulse into a diagnostic node of the STO circuit. The modified pulse has a voltage consistent with a voltage expected to be produced at the diagnostic node by a stop signal provided to the STO circuit.

Implementations of any of the techniques described herein may include an apparatus, a device, a system, and/or a method. The details of one or more implementations are set forth in the accompanying drawings and the description below. Other features will be apparent from the description and drawings, and from the claims.

### DRAWING DESCRIPTION

FIG. 1 is a block diagram of a safe torque off (STO) system that includes a logic control apparatus.

FIG. 2 is a block diagram of a system that includes another example of a logic control apparatus.

FIG. 3 is an example implementation of a voltage clamp circuit.

FIG. 4 is an example of a level shifter circuit.

FIG. 5 is a flow chart of a process performed during operation of the logic control apparatus of FIG. 2.

FIG. 6 is an example of a diagnostic signal and a boosted diagnostic signal.

FIG. 7 is a flow chart of an example of a detection process.

FIG. 8 shows examples of an output voltage, a second diagnostic signal, and a second output voltage as a function of time and

FIG. 9 is a block diagram of an example of a dual channel system.

FIG. 10 is a flow chart of an example of a process for performing a diagnostic on the system of FIG. 9.

### DETAILED DESCRIPTION

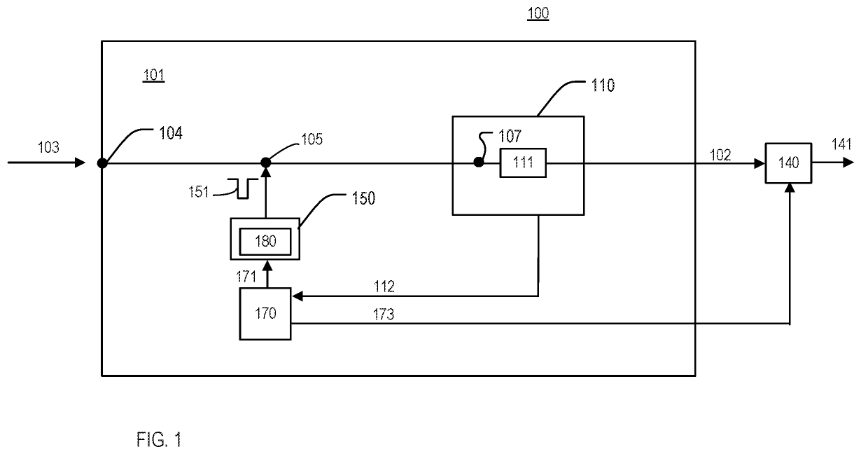

FIG. 1 is a block diagram of a safe torque off (STO) system 100 that includes a logic control apparatus 101. The logic control apparatus 101 includes an STO circuit 110 and a diagnostic circuit 150. The STO circuit 110 generates a control signal 102 to enable or disable a device 140 based on the voltage of an STO input node 104. When the voltage of the STO input node 104 indicates that an STO signal (or stop signal) 103 has been received, the controllable switch 111 should turn OFF and the device 140 should be disabled. The diagnostic circuit 150 injects a boosted diagnostic signal 151 to confirm that the controllable switch 111 is operating as expected.

The device 140 may be, for example, a modulation control driver signal switch for a motor drive apparatus. For example, the device 140 may be a pulse width modulation (PWM) driver signal switch for a variable frequency drive (VFD). When enabled, the device 140 produces an output 141. The output 141 may be, for example, a PWM signal to turn ON or OFF controllable switches (for example, insulating gate bipolar transistors (IGBT) in an inverter. When not enabled, the device 140 does not produce the output 141, the IGBTs are OFF, and the load will stop operating.

The stop signal 103 is provided to the STO input node 104 to intentionally disable the device 140. When the stop signal 103 is present, the voltage of the STO input node 104 has a stop voltage value (STOP_V). The stop voltage value (STOP_V) produces a corresponding voltage at a control input 107 of a controllable switch 111. For example, the controllable switch 111 may be a transistor such as a field effect transistor (FET) with a turn on threshold voltage and a turn off threshold voltage. A junction field effect transistor (JFET) and a metal oxide field effect transistor (MOSFET) are examples of field-effect transistors. When the controllable switch 111 is a FET, the control input 107 is the voltage between the gate and the source of the FET. The FET turns ON when the voltage of the control input 107 exceeds the turn on threshold voltage and is OFF when the voltage of the control input 107 is below the turn off threshold voltage.

The stop voltage value (STOP_V) should be sufficiently low such that the controllable switch 111 is OFF when the stop signal 103 is present. When the controllable switch 111 is OFF, the control signal 102 has a voltage value corresponding to not enabled or disabled. In other words, when the stop signal 103 is present, the controllable switch 111 should be OFF and the device 140 should not be enabled.

During normal operation, the stop signal 103 is not present and the voltage of the STO input node 104 has a run voltage value (RUN_V). The run voltage value (RUN_V) is different from the stop voltage value (STOP_V). The run voltage value (RUN_V) produces a voltage value at the control input 107 that causes the controllable switch 111 to be ON. For example, if the controllable switch 111 is a MOSFET, the run voltage value (RUN_V) causes the voltage between the gate and the source of the MOSFET to exceed the turn on threshold voltage such that the MOSFET turns ON.

The logic control apparatus 101 and the STO circuit 110 include components, such as resistors, diodes, transistors, and/or capacitors, that have parameters that may change over time and/or with changes in the operating environment. For example, a resistor is manufactured to have a certain nominal resistance, but the actual resistance of the resistor can be greater than or less than the nominal resistance due to variations in the manufacturing process. Moreover, the resistance of the resistor may change during its lifetime due to, for example, exposure to heat and electrical current during use. This variation in the resistance is referred to as parameter drift. Other electronic components can experience parameter drift. For example, the tube voltage drop of a diode may be +/−30% as compared to its nominal value. Transistors also experience parameter drift. For example, the turn on threshold voltage and/or turn off threshold voltage may vary over time and/or with the operating environment such that the actual turn on and/or turn off threshold voltage is not the value expected for the device.

Regardless of its source(s), parameter drift may lead to voltage variations in the logic control apparatus 101. For example, the expected voltage at the control input 107 when the stop signal 103 is present can be calculated based on the value of the stop voltage value (STOP_V) and the impedance of electrical components between the STO input node 104 and the control input 107. However, due to parameter drift of the electrical components between the STO input node 104 and the control input 107, the actual voltage at the control input 107 for a given voltage at the STO input node 104 may vary from its expected value. If the actual voltage of the control input 107 is higher than expected, it is possible that the controllable switch 111 remains ON and the device 140 remains enabled in the presence of the stop signal 103. Furthermore, the turn on voltage and/or turn off voltage of the controllable switch 111 may drift. For example, if the turn off voltage of the controllable switch 111 varies from its nominal value of 1 volt (V) to an actual value of 0.5 V, the stop voltage value (STO_V) may be inadequate to turn off the controllable switch 111. In this example, even if the voltage at the control input 107 is as expected, the controllable switch 111 remains ON and the device 140 remains enabled in the presence of the stop signal 103. Such a scenario is undesirable and may present a safety issue because the output 141 can continue to be produced while the operator is expecting that the output 141 has been halted.

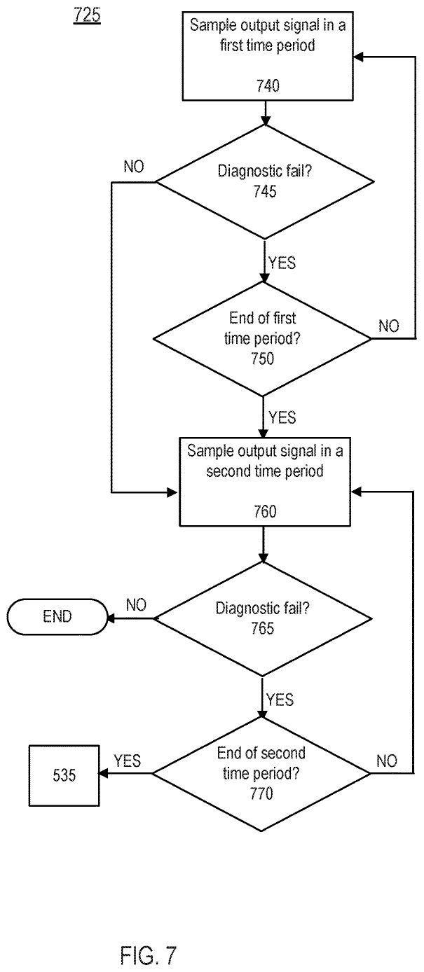

On the other hand, the logic control apparatus 101 includes the diagnostic circuit 150 and a control module 170, which provide a hardware and software based parameter drift monitoring to ensure that the logic control apparatus 101 operates in a proper and expected manner despite parameter drift. The diagnostic circuit 150 allows the logic control apparatus 101 to operate at a high safety level, for example, SIL3 Ple Cat4 or greater. The diagnostic circuit 150 is hardware-based in that it includes a level shifting circuit 180 that boosts a diagnostic pulse 171 from the electronic control module 170 into a boosted diagnostic signal 151. The boosted diagnostic signal 151 has a voltage that should be sufficient to cause the controllable switch 111 to turn OFF and to be detected as an output signal 112 at an output of the STO circuit 110. The diagnostic circuit 150 includes software aspects as well. For example, the control module 170 analyzes the output signal 112 to determine whether the controllable switch 111 is operating properly. If the controllable switch 111 is not operating properly, the control module 170 provides a fault signal 173 to the device 140 to disable the device 140. The control module 170 also uses a detection process (such as discussed with respect to FIG. 7) that is able to reliably detect the output signal 112 even in the presence of other pulsed voltage signals.

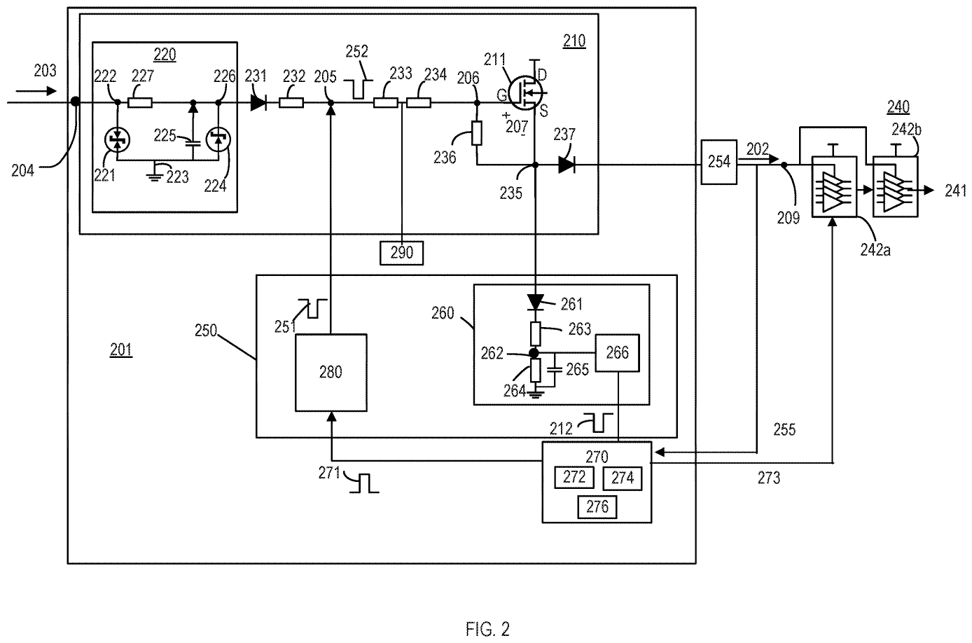

FIG. 2 is a block diagram of a system 200 that includes a logic control apparatus 201. The logic control apparatus 201 is an example implementation of the logic control apparatus 101 (FIG. 1). The logic control apparatus 201 includes an STO circuit 210 and a diagnostic circuit 250. The logic control apparatus 201 also includes a microcontroller 290. The microcontroller 290 may be used for monitoring a safety related power supply. In some implementations, the DSP 270 and the microcontroller 290 are combined into a single electronic control.

The STO circuit 210 generates a control signal 202 for a device 240. In the example shown, the device 240 is a PWM modulation driver signal switch that includes PWM buffers 242a, 242b. When the device 240 is enabled, PWM control signals 241 are provided to switches in a motor driver such that the switches turn on and off in a pattern defined by the PWM control signals 241 to produce power for a load. When the device 240 is not enabled, the PWM control signals 241 are not provided to the motor driver and the power is not available to the load.

The STO circuit 210 includes an STO input node 204 connected to a node 222 of an input circuit 220. The input circuit 220 includes a transient voltage suppressor (TVS) diode 221 that is electrically connected between a node 222 and ground, and a Zener diode 224 and a capacitor 225 that are electrically connected in parallel between a node 226 and ground. An impedance 227 is between the nodes 222 and 226. The impedance 227 is illustrated as a single element but may include more than one distinct resistor electrically connected to form the impedance 227. For example, the impedance 227 may include two impedances in series, where each of the two impedances is formed from two resistors connected in parallel. The TVS diode 221 absorbs transient overvoltages and the Zener diode 224 provides a stable voltage at the node 226. The capacitor 225 filters out high-frequency noise and mitigates the effect of noise on the components of the STO circuit 210.

The node 226 is electrically coupled to the anode of a diode 231. An impedance 232 is electrically connected between the cathode of the diode 231 and a diagnostic node 205. The impedance 232 and the diagnostic node 205 are connected to an impedance 233, which is connected to an impedance 234. Each of the impedances 232, 233, 234 is shown as a single element but may be a network of resistive components electrically connected in a network with an overall impedance. For example, the impedance 232 may be two or more resistors electrically connected in parallel, and the impedance 233 may be two or more resistors electrically connected in series.

The impedance 234 is connected to an input node 206 of a controllable switch 211. In the example of FIG. 2, the controllable switch 211 is a field-effect transistor (FET) that has a gate G, drain D, and a source S. The gate G of the FET 211 is electrically connected to the input node 206, the drain D of the FET 211 is electrically connected to a voltage supply, and the source S of the FET 211 is electrically connected to a node 235. An impedance 236 is electrically connected between the nodes 206 and 235. The voltage between the nodes 206 and 235 is a control input 207 and controls the state of the controllable switch 211. The switch 211 is associated with a turn on threshold voltage and a turn off threshold voltage. When the voltage of the control input 207 exceeds the turn on threshold voltage, the controllable switch 211 is ON, and, when the voltage of the control input 207 is less than the turn off threshold voltage, the switch 211 is OFF.

The impedance 236 is electrically connected to the anode of a diode 237 at node 235. The cathode of the diode 237 is electrically connected to a low pass filter 254, which is electrically connected to the device 240. The low pass filter 254 may be, for example, an R-C filter. The output of the low pass filter 254 is the control signal 202.

The diagnostic circuit 250 includes an output preparation circuit 260 and a level shifter circuit 280. The logic control apparatus 201 also includes a DSP 270 and a microcontroller 290. The DSP 270 generates a diagnostic signal 271, and the level shifter 280 boosts the voltage level of the diagnostic signal 271 to generate a boosted diagnostic signal 251. The output preparation circuit 260 includes a diode 261 and a voltage divider that includes impedances 263 and 264. The anode of the diode 261 is electrically connected to the node 235, and the cathode of the diode 261 is electrically connected to the impedance 263, which is electrically connected to the impedances 264. The impedance 264 is connected to ground, and the output of the voltage divider (the node 262 between the impedance 263 and 264) is electrically connected to a voltage clamp circuit 266.

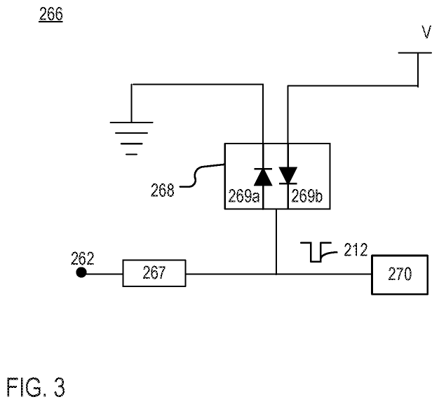

The voltage clamp circuit 266 protects the DSP 270 from high voltage that can be generated when the STO circuit 210 fails. FIG. 3 shows an example implementation of the voltage clamp circuit 266. The voltage clamp circuit 266 includes an impedance 267 and a diode assembly 268. The impedance 267 is electrically connected to the node 262 and to the diode assembly 268. The diode assembly 268 includes anti-parallel diodes 269a and 269b. The diode 269a is connected to ground, and the diode 269b is connected to a voltage supply V. When there is no fault in the STO circuit 210, the output signal 212 provided to the DSP 270 is the same as the output signal at the node 262.

Returning to FIG. 2, the DSP 270 includes an electronic processing module 272, an electronic storage 274, and an input/output interface 276. The electronic processing module 272 includes one or more electronic processors. The electronic processors of the module 272 may be any type of electronic processor and may or may not include a general-purpose central processing unit (CPU), a graphics processing unit (GPU), a microcontroller, a field-programmable gate array (FPGA), Complex Programmable Logic Device (CPLD), and/or an application-specific integrated circuit (ASIC).

The electronic storage 274 may be any type of electronic memory. In some implementations, the electronic storage 274 is capable of storing instructions in the form of computer programs or software. The electronic storage 274 may include volatile and/or non-volatile components. The electronic storage 274 and the processing module 272 are coupled such that the processing module 272 is able to access or read data from and write data to the electronic storage 274. The electronic storage 274 stores instructions that, when executed, cause the electronic processing module 272 to analyze data and/or retrieve information. The electronic storage 274 also stores values and specifications that are used to process the output signal 212. Furthermore, the electronic storage 274 stores executable instructions that cause the electronic processing module 272 to generate signals, such as the diagnostic signal 271 and a fault signal 273.

The I/O interface 276 is any interface that allows the DSP 270 to send and receive electrical signals. For example, the I/O interface 276 may include pins, ports, a display (such as a liquid crystal display (LCD)), a keyboard, audio input and/or output (such as speakers and/or a microphone), visual output (such as lights, light emitting diodes (LED)) that are in addition to or instead of the display, serial or parallel port, a Universal Serial Bus (USB) connection, and/or any type of network interface, such as, for example, Ethernet. The I/O interface 276 also may allow communication without physical contact through, for example, an IEEE 802.11, Bluetooth, or a near-field communication (NFC) connection. The DSP 270 and/or the information stored on the electronic storage 274 may be, for example, operated, configured, modified, or updated through the I/O interface 276.

The microcontroller 290 also includes an electronic processor, an electronic storage, and an I/O interface.

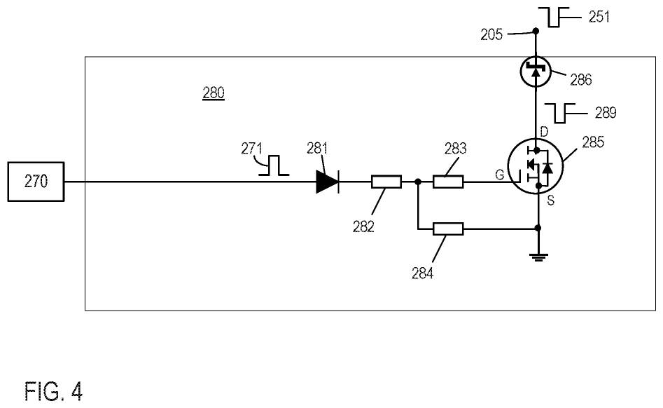

The level shifter circuit 280 receives the diagnostic signal 271 from the DSP 270 and generates the boosted diagnostic signal 251. FIG. 4 shows an example of the level shifter circuit 280. In the example shown in FIG. 4, the level shifter 280 includes a diode 281. The anode of the diode 281 is connected to an output pin of the DSP 270, and the cathode of the diode 281 is connected to an impedance 282, which is connected to an impedance 283 and an impedance 284. The impedance 283 is connected to a gate of a FET 285, and the impedance 284 is connected to the source of the FET 285. The drain of the FET 285 is connected to a Zener diode 286, which is connected to the diagnostic node 205.

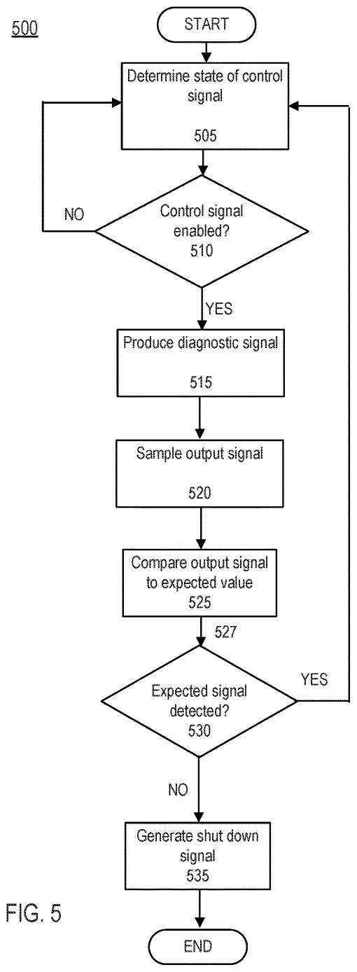

The operation of the logic control apparatus 201 is discussed next with reference to FIG. 5. FIG. 5 is a flow chart of a process 500 performed by the electronic processing module 272 of the DSP 270 during operation of the logic control apparatus 201.

The process 500 begins by determining the state of the control signal 202 (505). The control signal 202 has a HIGH state and a LOW state. When the control signal 202 is HIGH, the device 240 is enabled and produces the output 241. When the control signal 202 is LOW, the device 240 is not enabled and does not produce the output 241. An enable signal 255 represents the voltage at a node 209 and provides the voltage of the control signal 202 to the DSP 270. The node 209 is at the output of the low pass filter 254 and the input to the device 240. The voltage levels corresponding to the HIGH and LOW states of the control signal 202 are stored on the electronic storage 274. For example, the HIGH state may be defined as a voltage greater than 4V and the low state may be defined as a voltage lower than 2V. To determine the state of the control signal 202, the DSP 270 compares the voltage of the enable signal 255 to the defined states of the control signal 202. If the enable signal 255 is HIGH, the control signal 202 is enabled. If the enable signal 255 is LOW, the control signal 202 is not enabled.

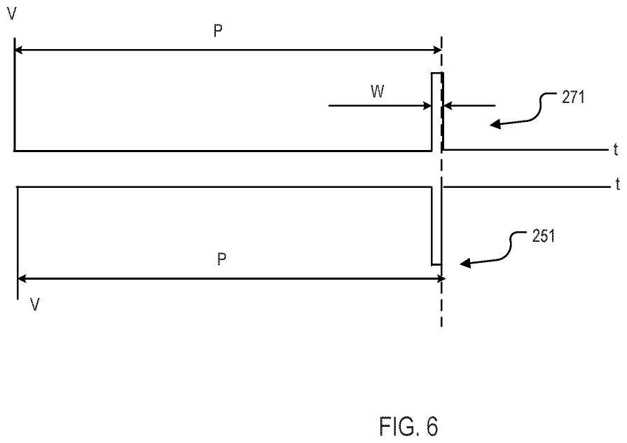

At (510), if the control signal 202 is not enabled, the device 240 is in the safe mode, and the process 500 returns to (505) to continue monitoring the state of the control signal 202. At (510), if the control signal 202 is enabled, the DSP 270 produces the diagnostic signal 271 to test the STO circuit 210 (515). Referring also to FIG. 6, which shows the voltage of the diagnostic signal 271 as a function of time in seconds, the diagnostic signal 271 has a period (P) and a duty cycle. The duty cycle is the percentage of the period (P) over which the diagnostic signal is continuously LOW. The diagnostic signal 271 is HIGH for the remainder of the period (P) for a time period W. For example, the period may be 100 milliseconds (ms) with a duty cycle of 99.9%. In this example, the diagnostic signal 271 is LOW (for example 0 V) for 99.9 ms and HIGH for 0.1 ms. In other words, W is 0.1 ms in this example. The LOW voltage value of the diagnostic signal 271 is 0V and the HIGH voltage value depends on the parameters of the DSP 270 any may be, for example, 2 to 3.5 V.

Referring also to FIGS. 2 and 4, the diagnostic signal 271 is provided to the level shifter circuit 280. When the diagnostic signal 271 is LOW, the FET 285 is OFF and the diagnostic signal 271 is grounded. When the diagnostic signal 271 is HIGH, the FET 285 turns ON and inverts the diagnostic signal 271 into an inverted diagnostic signal 289. The Zener diode 286 produces an essentially constant voltage at the node 205 at the voltage associated with the Zener diode 286. In this way, the level shifter circuit boosts the initial low voltage level of the inverted diagnostic signal 289 into the boosted diagnostic signal 251.

The pulse of the boosted diagnostic signal 251 has a voltage that corresponds to the stop voltage value (STOP_V) for the system 200. The stop voltage value (STOP_V) is the voltage of the STO input node 204 when the STO signal 203 is present. In other words, the stop voltage value (STOP_V) is the voltage of the STO node 204 when the device 240 is to be intentionally not enabled. The Zener diode 286 is selected to boost to the voltage level of the inverted diagnostic signal 289 to at least the voltage that is expected at the diagnostic node 205 when the STO signal 203 is present. Boosting the inverted diagnostic signal 289 in this manner allows the boosted diagnostic signal 251 to be used to ensure that the stop voltage value (STOP_V) at the STO input node 204 can reliably turn OFF the controllable switch 211. For example, in an implementation in which the STO input node has a voltage of 5V in the presence of the STO signal 203, and the impedances 227 and 232 are such that a 5V signal at the STO input node 204 nominally corresponds to a voltage of 4.59 V at the diagnostic node 205, the boosted diagnostic signal 251 should have a voltage level of at least 4.59V. In this example, a Zener diode with voltage of 5.1 V or 5 V may be used as the Zener diode 286.

The boosted diagnostic signal 251 is inserted into the STO circuit 210 at the diagnostic node 205 and produces a voltage at the control input 207 of the controllable switch 211. The pulse in the boosted diagnostic signal 251 is filtered out at the low pass filter 254 and does not appear at the node 209. Thus, the boosted diagnostic signal 251 does not interfere with the operation of the device 240 or the state of the control signal 202. The output signal 212 is generated and received at the DSP 270 (520). The DSP 270 compares the voltage of the received output signal 212 to an expected value of the output signal (525).

As discussed above, the pulse in the boosted diagnostic signal 251 produces voltage at the node 205 that is representative of what would be produced when the STO signal 203 is present. Thus, in the absence of parameter drift, the pulse in the boosted diagnostic signal 251 produces a voltage at the control input 207 sufficiently low to turn OFF the controllable switch 211. Moreover, the pulse in the boosted diagnostic signal 251 also produces an expected voltage at the node 235. When the boosted diagnostic signal 251 produces the expected voltage at the node 235, the output signal 212 also has a voltage as expected. When the output signal 212 has a voltage as expected, the STO circuit 210 is working as intended. For example, in an implementation in which the voltage at the diagnostic node 205 is 5.05 V during an intentional shutdown and the voltage at the node 235 when the controllable switch 211 is OFF is expected to be 0.36V or less, when the output signal 212 corresponds to the voltage at the node 235 being 0.3V, the output signal 212 has the expected voltage. A diagnostic flag is set to PASS to indicate that the output signal 212 has the expected voltage. At (530), the process returns to (505) to continue to monitor the control signal 202.

However, due to parameter drift, it is possible that the voltage at the control input 207 is larger than expected or that the turn off threshold of the controllable switch 211 has drifted such that the controllable switch 211 does not turn OFF in response to the boosted diagnostic signal 251. In this scenario, the voltage at the node 235 and the voltage of the output 212 are different than expected. The deviation indicates that the STO circuit 210 is not operating properly and that the STO signal 203 will not be able to disable device 240. Continuing with the example above in which, the expected voltage at the node 235 is less than 0.36V, if the output signal 212 has a voltage that indicates that the voltage at the node 235 is more than 0.36V, the output signal 212 does not have the expected voltage. The diagnostic flag 527 is set to FAIL to indicate that the STO circuit 210 is not working properly. At (530), the process 500 advances to (535) and the DSP 270 issues the fault signal 273. The fault signal 273 disables the device 240.

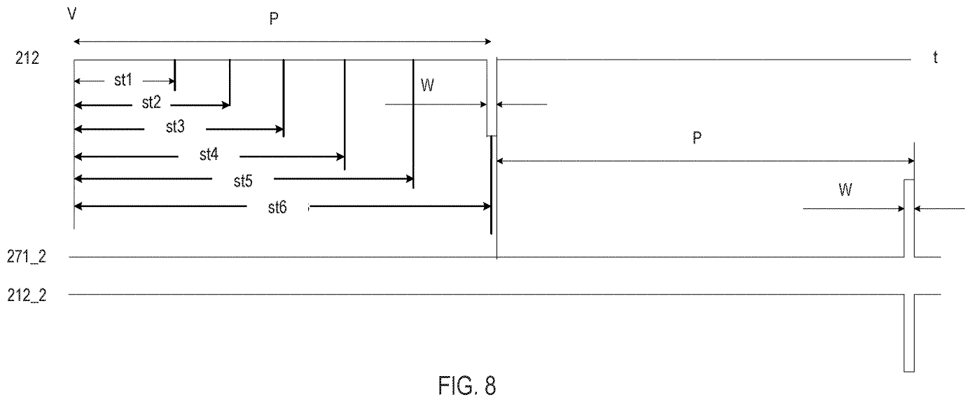

FIG. 7 is a flow chart of a process 725. The process 725 is an example of a process that can be used for (525) in the process 500. The process 725 is one possible implementation of comparing the output signal 212 to the expected value. The process 725 may help to identify the output signal 212 produced in response to the diagnostic signal 271, thus ensuring that the fault signal 273 is not erroneously produced based on another signal that may be propagating in the STO circuit 210. The process 725 is performed by the processing module 272 of the DSP 270. The process 725 is discussed with reference to FIG. 8, which shows the voltage of the output signal 212 produced in response to the diagnostic signal 271 as a function of time. The output signal 212 has the period P and a pulse having a temporal width W. The period (P) may be 100 ms and the duty cycle may be 99.9%. In this example, the temporal width is 0.1 ms.

The output signal 212 is sampled in a first time period (740). The first time period is the time period that corresponds to the time period during which the diagnostic pulse 271 is LOW. Continuing the example above, the first time period is from 0 ms to just before 99.9 ms. The voltage of the output signal 212 is sampled at the end of a first subperiod (st1) and compared to the expected voltage. The controllable switch 211 should be ON, and the expected voltage is known based on the characteristics of the controllable switch 211. For example, in an implementation in which the voltage at the diagnostic node 205 is 14.8 V during normal operation and the voltage at the node 235 when the controllable switch 211 is ON is expected to be 4.68 V or greater, when the voltage of the output signal 212 corresponds to the voltage at the node 235 being 5V, the output signal 212 has the expected voltage and there is no failure condition. At (745), the process 725 advances to (760).

On the other hand, if the voltage of the output signal 212 indicates that the voltage at the node 235 is less than 4.68 V, there is a diagnostic failure for the sample taken at the end of the first subperiod st1. In this case, at (745), the process 725 advances to (750). If the first portion of the output signal 212 has not ended, the process 725 returns to (740) and obtains another sample of the output signal 212 at a time when the diagnostic signal 271 is LOW. In the example shown in FIG. 8, a total of five samples of the output voltage 212 are obtained at different times while the diagnostic signal 271 is LOW. The samples are not necessarily obtained at a regular interval. If all five samples have voltages that are different than expected, a high-level diagnostic failure is present. Although five samples are used in this example, more or fewer samples may be taken during the first time period (while the diagnostic signal 271 is LOW).

The output voltage 212 is sampled during a second time period (760). During the second time period, the diagnostic signal 271 is HIGH and the controllable switch 211 is expected to be turned OFF. For example, in an implementation in which the voltage at the diagnostic node 205 is 5.05 V during an intentional shutdown and the voltage at the node 235 when the controllable switch 211 is OFF is expected to be 0.36V or less, when the output signal 212 corresponds to the voltage at the node 235 being 0.3V, the output signal 212 has the expected voltage. If the output signal 212 has the expected voltage, there is no diagnostic failure (765), and the process 725 ends and may resume with the next diagnostic pulse. If the output signal 212 does not have the expected voltage, there is a diagnostic failure (765). Additional samples may be observed in the second time period. If the second time period has ended (770), the fault signal 273 is generated at (535).

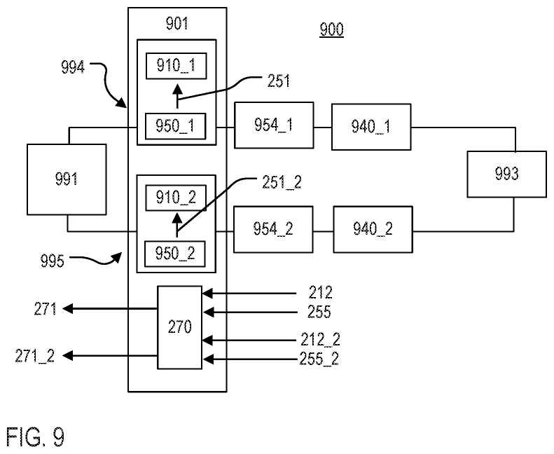

FIG. 9 is a block diagram of a dual channel system 900. The dual channel system 900 includes a power supply 991 and inverter IGBTs 993, and a logic control apparatus 901 that includes a safe torque off for the inverter IGBTs 993. The system 900 includes two parallel channels: a first channel 994 and a second channel 995. The first channel includes an STO circuit 910_1 and a diagnostic circuit 950_1, a low pass filter 954_1, and a device 940_1. The device 940_1 is a PWM driver signal switch. When enabled, the device 940_1 outputs PWM signals to drive the inverter IGBTs 993. The STO circuit 910_1 is the same as the STO circuit 210, the diagnostic circuit 950_1 is the same as the diagnostic circuit 250, and the low pass filter 954_1 is the same as the low pass filter 254.

The second channel 995 is identical to the first channel 994. The second channel 995 includes an STO circuit 910_2 and a diagnostic circuit 950_2, a low pass filter 954_2, and a device 940_2. The device 940_2 is a PWM driver signal switch. When enabled, the device 940_2 outputs PWM signals to drive the inverter IGBTs 993. The STO circuit 910_2 is the same as the STO circuit 210, the diagnostic circuit 950_2 is the same as the diagnostic circuit 250, and the low pass filter 954_2 is the same as the low pass filter 254.

The DSP 270 is configured to send signals to the diagnostic circuits 950_1 and 950_2 and to the devices 940_1 and 940_2. The DSP 270 is configured to receive signals from the STO circuits 910_1 and 910_2 and from the output of each low pass filter 954_1 and 954_2. The STO circuit 910_1 produces an output signal 212 in response to receiving the diagnostic pulse 271. The STO circuit 910_2 produces an output signal 212_2 in response to receiving a diagnostic pulse 271_2.

The channels 994 and 995 are independent and separate. Including two channels provides redundancy and may allow the system 900 to be certified at a higher level than a single channel system. For example, if the STO circuit 910_1 fails, the STO circuit 910_2 can continue to operate to provide the safe torque off functionality. Moreover, although two channels 994 and 995 are include in the system 900, additional independent, identical, parallel channels may be added for additional redundancy.

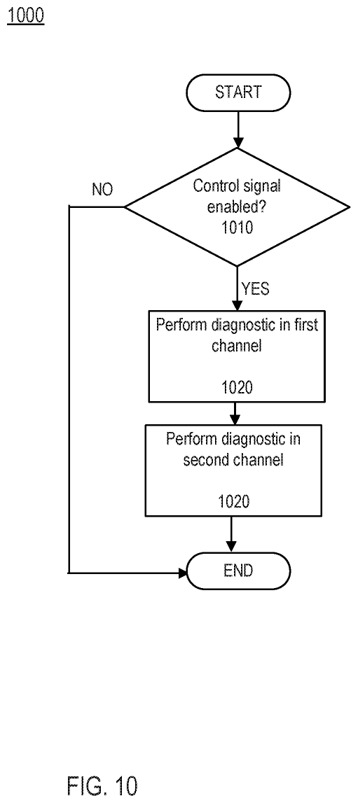

FIG. 10 is a flow chart for performing a diagnostic on the system 900. If the control signal 202 is enabled, the diagnostic is performed on the first channel 994 (1020). For example, all or part of the process 500 and the process 725 may be performed on the first channel 994. After completing the diagnostic on the first channel 994, the same diagnostic is performed on the second channel 995 (1020). The diagnostic is not performed on both channels 994 and 995 at the same time to avoid potential interference between detecting the output signal 212 in the first channel 994 and the output signal 212_2 in the second channel 995. Referring to FIG. 8, the output signal 212_2 is shown as a function of time. The output signal 212_2 is the same as the output signal 212, except the output signal 212_2 occurs after the output signal 212 due to the diagnostic signal 271_2 being generated and provided to the diagnostic circuit 950_2 after the diagnostic signal 271 is provided to the diagnostic circuit 950_1.

These and other implementations are in the scope of the claims.

What is claimed is:

1. A system comprising:
a safe torque off (STO) circuit comprising a controllable switch, the STO circuit configured to generate a control signal for a device, wherein the control signal has a first state that enables the device when the controllable switch is ON, and the control signal has a second state that does not enable the device when the controllable switch is OFF;
an electronic control configured to generate a diagnostic signal when the control signal has the first state; and
a diagnostic circuit configured to:
modify a voltage of the diagnostic signal to produce a modified diagnostic signal, wherein the modified diagnostic signal comprises a pulse with a voltage expected to turn OFF the controllable switch; and
provide the modified diagnostic signal to the STO circuit to produce an output signal,
wherein the electronic control is further configured to: compare the output signal to a specification; and, if the output signal does not meet the specification, generate a fault signal.

2. The system of claim 1, wherein the specification is an expected voltage range for the output signal when the controllable switch is OFF, and the output signal does not meet the specification if the voltage of the output signal is outside of the expected voltage range.

3. The system of claim 2, wherein the diagnostic circuit is configured to: provide the modified diagnostic signal to the STO circuit at a diagnostic node, and the voltage of the pulse is the same or greater than a voltage that a stop signal received at the STO circuit is expected to produce at the diagnostic node.

4. The system of claim 1, wherein the controllable switch comprises a transistor.

5. The system of claim 1, wherein the diagnostic circuit comprises a level shifter.

6. The system of claim 5, wherein the level shifter comprises a Zener diode.

7. The system of claim 1, wherein electronic control is configured to compare a first portion of the output signal to a first specification, and a second portion of the output signal to a second specification.

8. The system of claim 7, wherein the first specification is an expected voltage range for the output signal when the controllable switch is ON, and the second specification is an expected voltage range for the output signal when the controllable switch is OFF.

9. The system of claim 1, wherein the electronic control is further configured to identify the output signal.

10. The system of claim 1, further comprising the device.

11. The system of claim 10, wherein the device comprises a pulse width modulation (PWM) driver signal switch configured to output PWM signals when enabled.

12. The system of claim 10, further comprising a low pass filter between the STO circuit and the device, the low pass filter configured to prevent the modified diagnostic signal from reaching the device.

13. The system of claim 10, wherein, if the output signal does not meet the specification, the electronic control is further configured to provide the fault signal to the device such that device transitions to a not enabled state.

14. A control system configured to:
generate a diagnostic signal comprising a period, and the diagnostic signal being LOW during a first portion of the period and HIGH during a second portion of the period;
provide the diagnostic signal to a boosting module to produce an output voltage of a safe torque off (STO) circuit;
sample the output voltage at one or more times during a first time window, the first time window corresponding to the first portion of the period;
compare the one or more voltages sampled during the first time window to a first voltage specification;
sample the output voltage during a second time window, the second time window corresponding to the second portion of the period;
compare the voltage sampled during the second time window to a second voltage specification; and
if the voltage sampled during the second time window does not meet the second voltage specification, generate a fault signal.

15. The control system of claim 14, wherein the output voltage is sampled more than one time during the first time window, and the control system is configured to generate the fault signal if the voltages sampled in the second time window does not meet the second voltage specification and if all of the voltage sampled in the first time window do not meet the first voltage specification.

16. The control system of claim 14, wherein the first voltage specification comprises a voltage range expected when a controllable switch in the STO circuit is ON, and the second voltage specification comprises a voltage range expected when the controllable switch in the STO circuit is OFF.

17. The control system of claim 14, wherein the control system is configured to generate the diagnostic signal in response to determining that a control signal generated by the STO circuit is in an enabled state.

18. The control system of claim 15, wherein the control system is further configured to:
after the period ends, if the voltages sampled during the first time window meet the first voltage specification and the voltage sampled in the second time window meets the second voltage specification, generate a second diagnostic signal having the period;
provide the second diagnostic signal to a second boosting module to produce a second output voltage in a second safe torque off (STO) circuit;
sample the second output voltage at one or more times during a first time window, the first time window corresponding to the first portion of the period of the second diagnostic signal;
compare the one or more voltages sampled during the first time window to the first voltage specification;
sample the output voltage during a second time window, the second time window corresponding to the second portion of the period of the second diagnostic signal;
compare the voltage sampled during the second time window to the second voltage specification; and
if the voltage sampled during the second time window does not meet the second voltage specification, generate a fault signal.

19. A diagnostic module for an STO circuit, the diagnostic module comprising:
an input configured to receive a diagnostic voltage pulse;
an inverting element configured to invert the diagnostic voltage pulse into an inverted diagnostic voltage pulse; and
a voltage boosting element configured to modify the voltage of the inverted diagnostic voltage pulse into a modified pulse and to inject the modified pulse into a diagnostic node of the STO circuit, wherein the modified pulse has a voltage consistent with a voltage expected to be produced at the diagnostic node by a stop signal provided to the STO circuit.
